(19) United States
(12) Patent Application Publication
(10) Pub. No.: US 2012/0146358 A1
(43) Pub. Date: Jun. 14, 2012

(54) PROTECTIVE COVERING SYSTEM FOR A MOTOR VEHICLE

(76) Inventors: Jocelyne Sassi, Rueil Malmaison (FR); André Sassi, Rueil Malmaison (FR)

(21) Appl. No.: 13/382,461

(22) PCT Filed: Jul. 5, 2010
(86) PCT No.: PCT/FR10/51406

§ 371 Date: Feb. 29, 2012

(30) Foreign Application Priority Data
Jul. 6, 2009 (FR) 09 54642

(51) Int. Cl. B60J 11/02; H01L 31/045

(52) U.S. Cl. 296/136.12; 136/245

(57) ABSTRACT

A protective tarpaulin system (1) for a motor vehicle (V), such as a car, said system comprising a flexible tarpaulin (6) for covering the vehicle, at least in part, so as to protect it, the tarpaulin (6) defining a longitudinal direction (L) that extends lengthwise over the vehicle, said system being characterized in that the tarpaulin (6) is provided with at least one stiffener element (61) that extends substantially in the longitudinal direction (L) so as to impart a certain stiffness to the flexible tarpaulin so as to make the operation of covering the vehicle with the tarpaulin easier.

The present invention relates to a protective tarpaulin system for a motor vehicle, such as a car including a rear bumper, a trunk, a roof, a hood, and a front bumper. The flexible tarpaulin is for covering the vehicle, at least in part, so as to protect it by extending from its rear bumper to its front bumper. The tarpaulin defines a longitudinal direction that extends lengthwise over the vehicle from the rear to the front. In other words, the tarpaulin is extended or pulled in the longitudinal direction so as to cover the vehicle from the rear to the front, or vice versa. Consequently, The advantageous field of application of the present invention is the field of privately-owned cars, but the present invention may also be used with other types of vehicle, e.g. commercial vehicles, trucks, trailers, boats, etc.

Protective tarpaulins for motor vehicles have long been in existence. The simplest models provide only a flexible tarpaulin that is unfolded and pulled over the top of the vehicle so as to cover it, at least in part. Once in place, the tarpaulin may be fastened to the vehicle using various techniques, e.g. rubber bands, hooks, etc. That type of rudimentary protective tarpaulin presents two drawbacks. The first resides in the covering operation that consists in extending the tarpaulin over the top of the vehicle. It is necessary to pass several times around the vehicle in order to position the tarpaulin correctly on the vehicle. The other drawback resides in the storage of the tarpaulin when it is not in use on the vehicle. It is necessary to fold the tarpaulin correctly so that it is as compact as possible. The storage drawback is solved, in part, by more complex protective tarpaulin systems that use a winding drum onto which the protective tarpaulin is wound in its storage position. When it is desired to use the tarpaulin, it is pulled by a free end in such a manner as to wind the tarpaulin out from its winding drum. Such winding drums may be installed at the front or at the rear, or on the roof of the vehicle. It is also possible to incorporate the winding drum inside the rear trunk or boot of the vehicle. However, even with a winding drum, the tarpaulin system does not solve the problem associated with the operation of covering the vehicle with the tarpaulin. It is still necessary to pull on the free end of the tarpaulin and to move about so as to extend the flexible tarpaulin in appropriate manner over the top of the vehicle. In other words, the winding drum is useful and effective during the operation of winding in the tarpaulin or of uncovering the vehicle, but it is of absolutely no use in the operation of winding out the tarpaulin or of covering the vehicle.

An object of the present invention is to make the operation of covering the vehicle with tarpaulin easier, so that putting it into place requires little, if any, intervention by the user. The present invention preferably applies to a tarpaulin system that uses a winding drum, but that is not limited to this single embodiment. Another object of the present invention is to make the operation of covering the vehicle with a tarpaulin easier and automated, without however hindering or complicating the operation of removing the tarpaulin. Still another object of the invention is to make the operation of applying a tarpaulin easier, without providing the tarpaulin with a rigid structure that needs to be removed, folded, or retracted by means of complicated mechanisms.

To do this, the present invention provides a protective tarpaulin system for a motor vehicle, such as a car, said system comprising a flexible tarpaulin for covering the vehicle, at least in part, so as to protect it, the tarpaulin defining a longitudinal direction that extends lengthwise over the vehicle, the tarpaulin being provided with at least one stiffener element that extends substantially in the longitudinal direction so as to impart longitudinal stiffness to the flexible tarpaulin so as to make the operation of covering the vehicle with the tarpaulin easier, the system further comprising a winding drum that is advantageously installed at the rear bumper of the vehicle, the tarpaulin being windable onto the drum between a wound-in storage position and a wound-out covering position, said at least one stiffener element extending substantially perpendicularly to the drum, said at least one stiffener element being windable onto the winding drum or onto a winding shaft that is distinct from the drum, said system being characterized in that it further comprises a motor for turning the winding drum about its own axis.

Advantageously, the tarpaulin system further comprises guide means for longitudinally guiding said at least one stiffener element while it is being wound in and/or wound out. Preferably, the guide means comprise two rotary presser rollers between which the stiffener element passes while it is being wound out and/or wound in.

Advantageously, said at least one stiffener element is provided with activator means that act on the stiffener element so as to switch it selectively between an activated state in which the stiffener element is substantially stiff, and a deactivated state in which the stiffener element is limp. This is a very advantageous characteristic of the invention that consists in using one or more stiffener elements having a state that may be controlled to be temporarily stiff during the operation of covering the vehicle with tarpaulin, and during the remainder of the time to be limp or flexible, so as to restore all of its qualities of flexibility to the tarpaulin. In an advantageous embodiment, the tarpaulin includes at least two stiffener elements that are advantageously interconnected via a junction element that may optionally be stiff. However, more than two stiffener elements could be provided, some extending, not in the longitudinal direction, but transversally or even perpendicularly to the longitudinal direction. The stiffener elements may present a configuration that is substantially rectilinear or, on the contrary, that is curved.

In a particularly advantageous aspect, said at least one stiffener element comprises an inflatable hose that is inflated with a fluid under pressure. Advantageously, the activator means comprises inflator means, such as a pump or a compressor, that are in fluid communication with said at least one stiffener element. Preferably, the tarpaulin includes a free end for covering the front of the vehicle, and a connection end that is secured to the winding drum, said stiffener element extending between the free and connection ends, the inflator means being connected to said at least one stiffener element via a feed tube that is connected to said stiffener element in the proximity of the free end, so as to inflate it from the free end to the connection end. Preferably, said at least one stiffener element and/or the feed tube extends in slightly sloping manner relative to the longitudinal direction, so as to avoid thicknesses accumulating in the wound storage position.

In a variant embodiment, the guide means comprise two rotary presser rollers that exert local leaktight pinching on the inflatable hose while it is being wound out, thereby preventing the portion that is still wound on the drum from being inflated. Advantageously, the tarpaulin, the stiffener element, and the feed tube can be wound around the winding drum in separate manner, so as to avoid creating excess thickness in the wound state.

Thus, the invention envisages using one or more inflatable hoses or tubes that are inflated with a fluid under pressure that is generally air. However, other gases or liquids could be used. In its non-inflated state, the hose is completely flexible, and preferably flat, so that it does not spoil the flexibility and the thickness of the tarpaulin. The tarpaulin with its deflated hose may thus be wound very easily onto the winding drum. In contrast, in its inflated state, the hose becomes stiff or rigid under the effect of the fluid under pressure contained therein. This thus imparts rigidity or stiffness to the tarpaulin that enables it to extend over the vehicle like a substantially rigid plate. Naturally, it is preferable for the hose(s) to extend in the longitudinal direction, given that the tarpaulin is wound out in said direction. However, so as to avoid winding the hose onto itself, it is preferable for it to extend at a slight slope relative to the winding drum, so that it is wound in a helical spiral around the drum. The same applies for the small feed tube that connects the pump or compressor to the hose. In addition, by making provision for inflating the hose(s) from the leading end of the tarpaulin, it is possible to avoid inflating the portion of the hose(s) that is still wound on the winding drum. This avoids any risk of blocking the tarpaulin inside its container as a result of the hose inflating. In other words, only the portion of the hose that has already been wound out from the drum is inflated with the fluid under pressure, the portion that is still wound remaining flat.

In a different second embodiment, said at least one stiffener element comprises a windable strip that is substantially straight and rigid in its wound-out state. By way of example, it is possible to use a shaped metal strip, such as the strips of roll-up tape rules. Advantageously, the strip is wound around a specific winding shaft that extends parallel to the winding drum, the strip advantageously being driven towards its wound-out state by the drum. By way of example, it is possible to provide a notched strip that is turned by the drum that is itself notched, like a rack.

In another advantageous aspect of the invention that is applicable to all embodiments, the drum is housed in a container that is advantageously installed at the rear bumper of the vehicle, the container including an elongate slot through which the tarpaulin can pass, the slot being provided with an outlet deflector that is suitable for directing the tarpaulin towards the top of the vehicle, the deflector advantageously serving as a pivoting closure lid for closing the slot. Given that the portion of the tarpaulin that is wound out is substantially rigid because of the stiffener elements, it is necessary to direct it in appropriate manner towards the top of the vehicle, so that the tarpaulin can be slid forwards over the vehicle until it reaches the front of the vehicle. The direction imposed on the wound-out tarpaulin is provided by the outlet deflector having a direction in use that is predetermined. Advantageously, the deflector may serve as a closure lid for closing the slot of the container when the tarpaulin is in its storage position inside its container.

In another common aspect, said at least one stiffener element is connected to the tarpaulin only at its free end for covering the front of the vehicle, so as to enable the stiffener element and the tarpaulin to be wound separately.

In a practical aspect, the tarpaulin system may further comprise mounting means, advantageously by snap-fastening, that are capable of mounting the tarpaulin system on the vehicle, preferably at the rear of the vehicle, the vehicle being fitted with a mounting device fastened on the structure of the vehicle. By way of example, provision may be made to fasten a metal plate on the structure at the location of a conventional towing hitch.

According to another characteristic of the invention, the tarpaulin system further comprises a traction device that is situated at the front of the vehicle, and that is connectable to the tarpaulin so as to guide it in the longitudinal direction.

In another aspect, the tarpaulin includes a zone that is covered in photovoltaic cells.

A principle of the invention is to fit the flexible tarpaulin with stiffener elements that are windable on a drum that is turned by a motor so as to wind out and/or wind in the tarpaulin and its stiffener elements.

Another principle is to provide guide means so as to hold the stiffener elements in the longitudinal axis of the vehicle, so as to make it easier to wind out and/or wind in said stiffener element.

Another principle of the invention resides in providing the flexible tarpaulin with stiffener elements that act only temporarily during the operation of applying the tarpaulin, but that do not act during the operation of removing the tarpaulin so as not to interfere with or hinder storage of the tarpaulin, whether this be by winding or by some other system.

The invention is described more fully below with reference to the accompanying drawings which show two embodiments of the invention by way of non-limiting example.

In the figures:

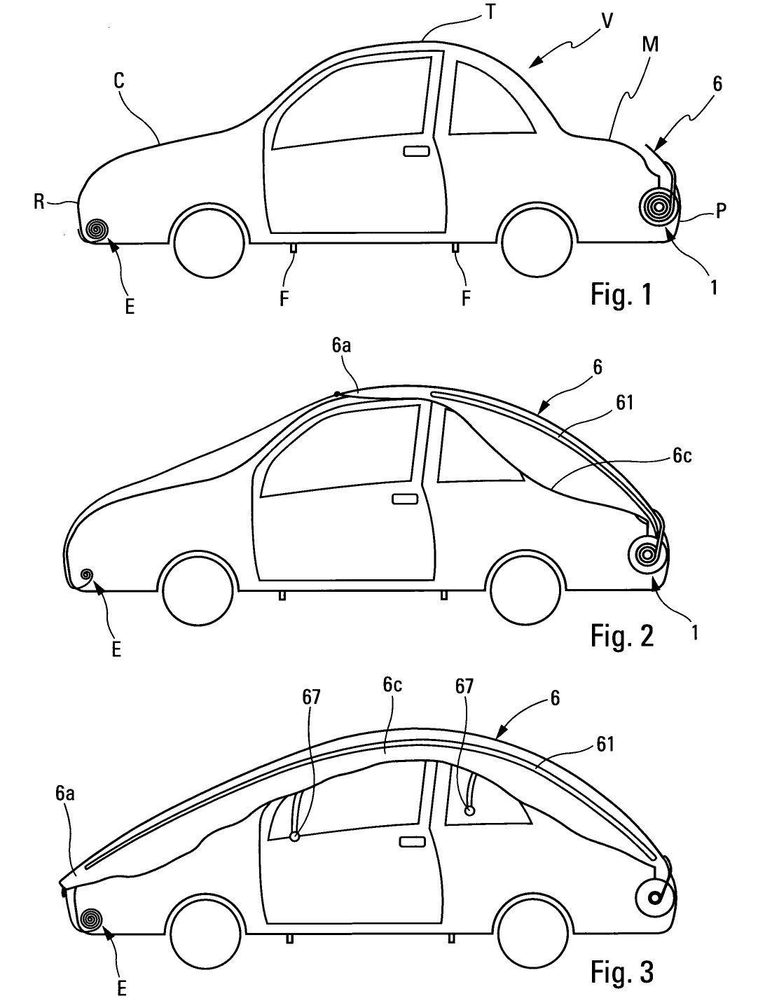

FIGS. 1 to 4 show, in very diagrammatic manner, a vehicle fitted with a protective tarpaulin system of the invention during various steps of covering the vehicle;

FIG. 5 is a greatly enlarged longitudinal section view of the rear portion of the vehicle incorporating the tarpaulin system of the invention;

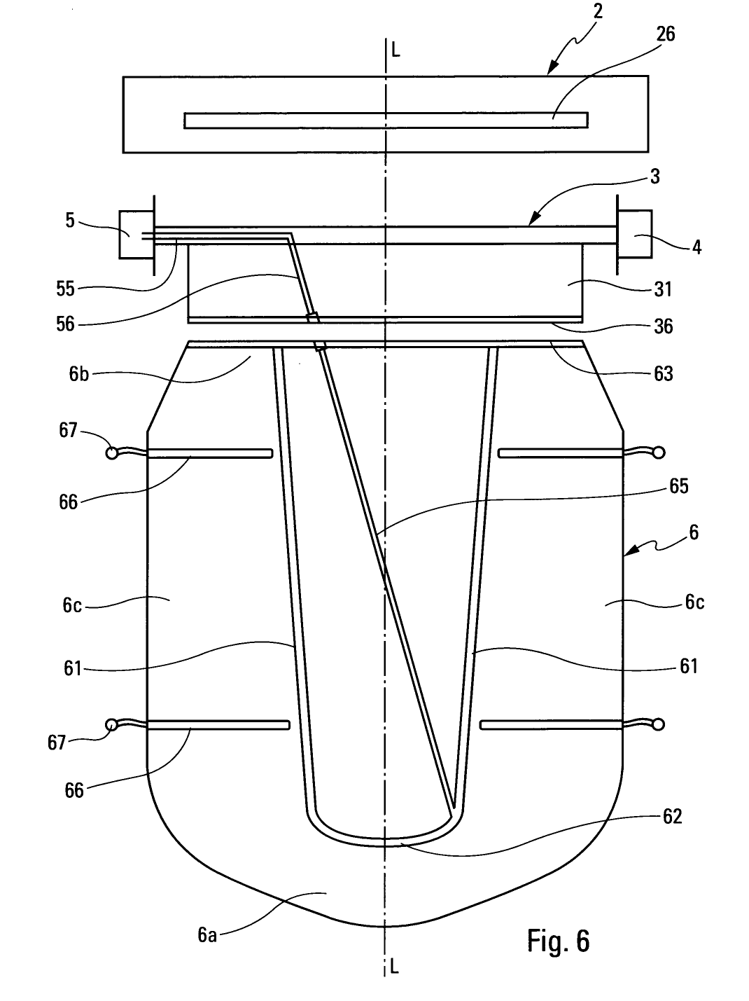

FIG. 6 is a very diagrammatic exploded view of the tarpaulin system of the invention in a first non-limiting embodiment;

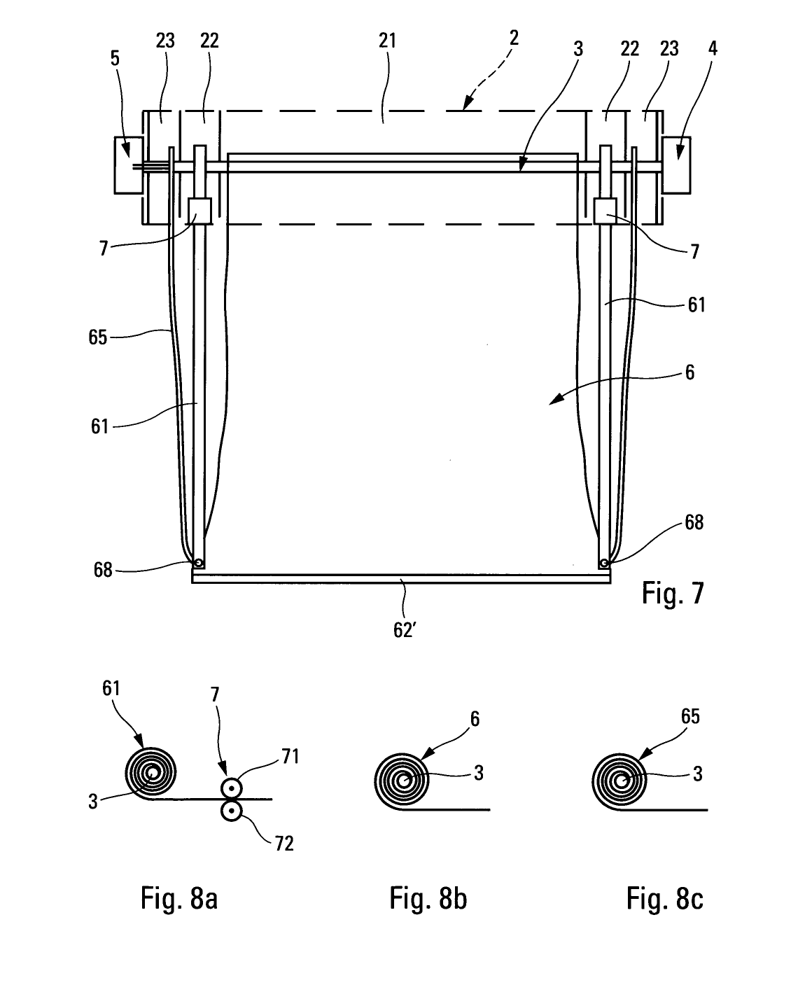

FIG. 7 is a diagrammatic representation of a tarpaulin system in a variant of the first embodiment in FIG. 6;

FIGS. 8a, 8b, and 8c are very diagrammatic cross-section views at three different locations of the FIG. 7 tarpaulin system;

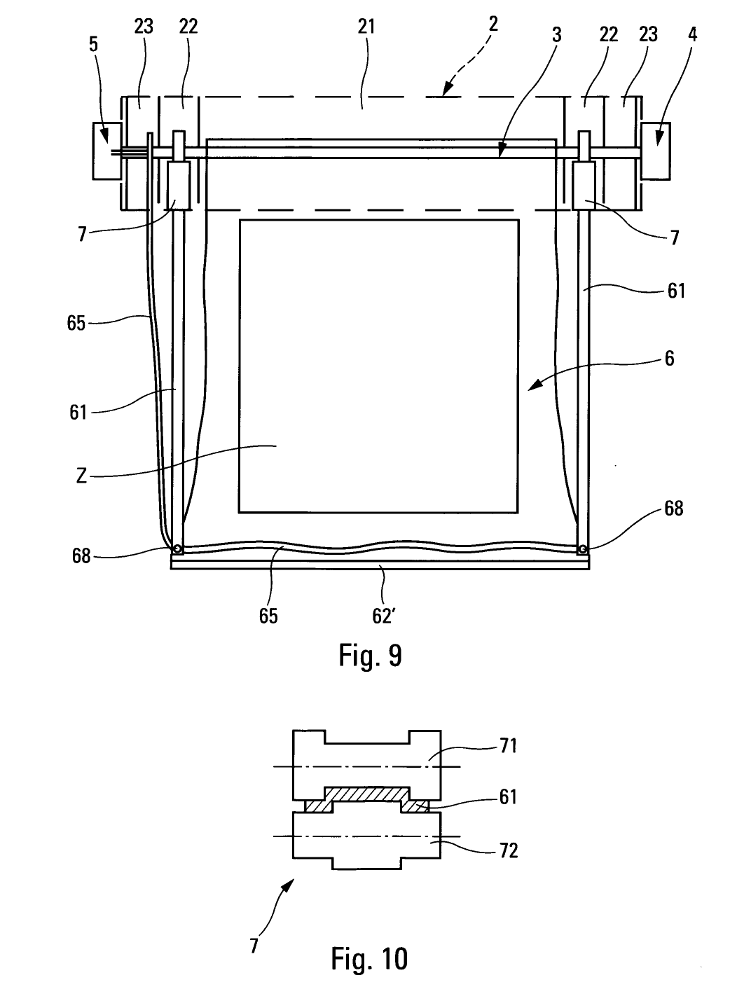

FIG. 9 is a diagrammatic representation of a second embodiment of the invention;

FIG. 10 is a larger-scale diagrammatic representation of the guide and pinching means in FIG. 9;

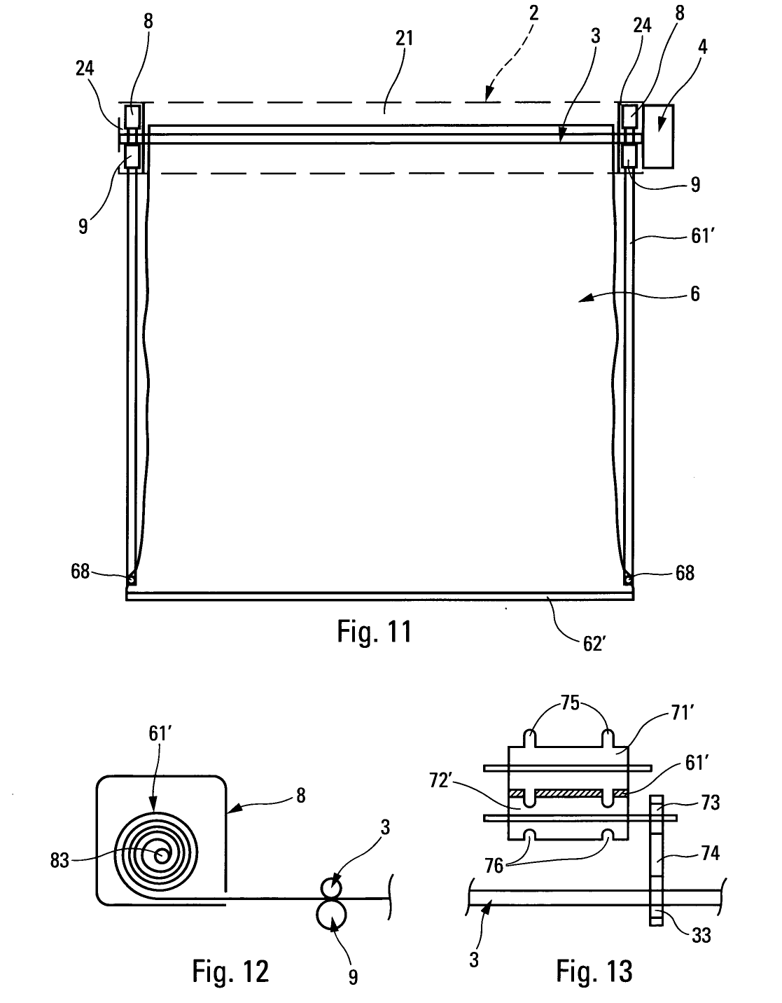

FIG. 11 is a diagrammatic representation of a third embodiment of the invention;

FIG. 12 is a larger-scale diagrammatic representation of the guide means in FIG. 11; and

FIG. 13 is a larger-scale diagrammatic representation of a variant embodiment of the guide means in FIG. 11.

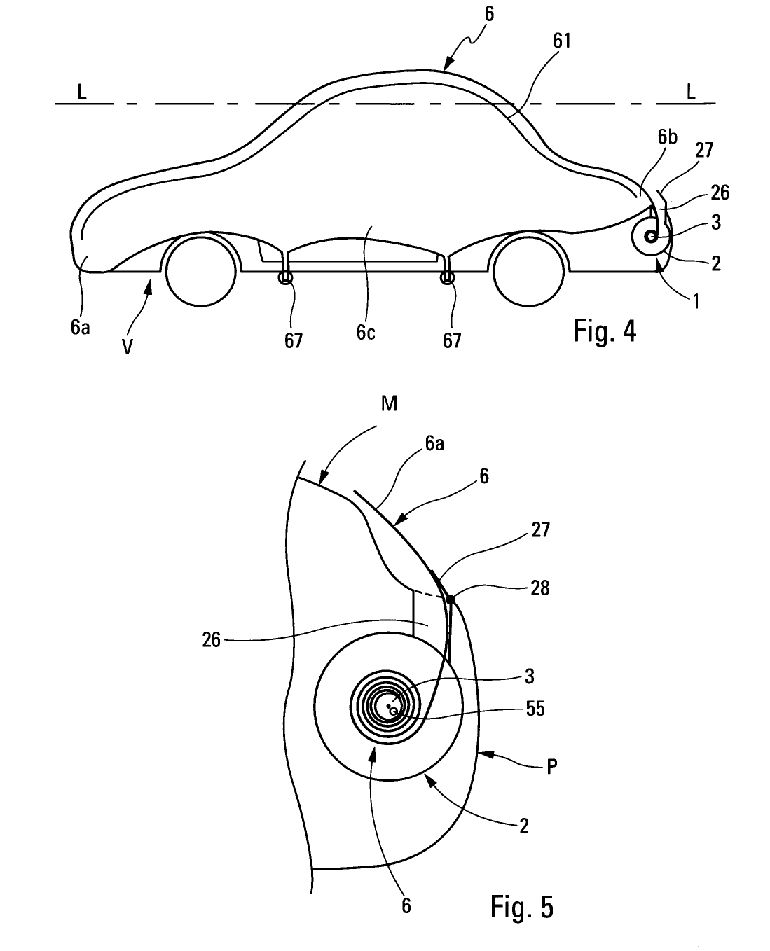

The protective tarpaulin system of the present invention is designated overall by the numerical reference 1 in the various accompanying figures. The tarpaulin system is for associating with, mounting on, adding to, or incorporating in a motor vehicle, such as a privately-owned car or a commercial vehicle, a truck, a trailer, or even a boat. It is even possible to envisage using the tarpaulin system of the invention to cover other optionally-movable objects, and even structures, e.g. a pool, a swimming pool, etc. In FIGS. 1 to 5 that are used to illustrate the present invention, the tarpaulin system is incorporated in a motor vehicle of the privately-owned type. In conventional manner, the vehicle V comprises a chassis, a plurality of wheels, an engine, and a body. The vehicle V also comprises a rear bumper P, a rear trunk M, a roof T, a front hood C, and a front bumper, as visible in FIG. 1. The top of the vehicle for covering with tarpaulin by means of the tarpaulin system of the invention is thus constituted by the rear trunk M, the roof T, the hood C, and a portion of the rear and front bumpers P and R. Naturally, the tarpaulin system also serves to cover, at least in part, the sides of the vehicle V, in which sides the driver and passenger doors are situated. Finally, as shown in FIG. 4, the tarpaulin system of the invention covers practically all of the car, with the exception of the wheels and a portion of the rear bumper. This is merely one non-limiting embodiment.

In the embodiment used to illustrate the present invention, the tarpaulin system 1 of the invention is incorporated inside the rear bumper P, as visible in FIGS. 1 to 5. The tarpaulin system 1 preferably extends over practically the entire width of the rear bumper P. This constitutes only a non-limiting embodiment, since it is also possible to mount the tarpaulin system of the invention elsewhere on the vehicle V, e.g. outside the bumper P, on or in the rear trunk M, on the roof T, or outside or inside the front bumper R. By way of example, it is possible to mount the tarpaulin system of the invention in removable manner at the rear bumper P, like a trailer or a caravan. By way of example, this can be done by fastening a mounting device on the chassis, instead of the trailer or caravan hitch, the device including means that enable the tarpaulin system to be mounted, advantageously by snap-fastening. In use, the tarpaulin system of the invention is fastened to the rear of the vehicle, and when the tarpaulin system is not in use, it may quite simply be stored inside the car, e.g. in the rear trunk. It should thus be considered that the tarpaulin system of the invention is in the form of a kit that may be put into place on the vehicle at will. It is also possible to envisage an equivalent system that enables the tarpaulin system to be mounted on the roof T of the vehicle like a roof rack. When the tarpaulin system of the invention is removable, it is naturally necessary to provide electrical connection means that enable the tarpaulin system to be powered electrically using energy from the vehicle, in general its battery. Whether the tarpaulin system of the invention is incorporated in the vehicle or, on the contrary, is removable, its structure and operation are substantially identical or equivalent.

Reference is made below to FIG. 6 that shows, in diagrammatic manner, all of the component elements of the protective tarpaulin system of the invention. Thus, the tarpaulin system includes a container 2 that internally defines a housing that communicates with the outside through an elongate slot 26. By way of example, the container 2 may present a cross-section that is substantially circular, and a length that is shorter than the width of the vehicle. It is thus possible to incorporate the container 2 inside the rear bumper P of the vehicle V, as shown in FIGS. 1 to 5. The tarpaulin system also includes a winding drum 3 that is in the form of an elongate shaft or pin that is suitable for being turned about its own axis by an electric motor 4 that is mounted at one of its ends. The drum 3 and the motor 4 are for housing inside the container 2. However, in FIG. 6, the elements are shown extracted from the container 2 for the purpose of clarity. At its other end, the drum 3 is fitted with inflator means 5 that may be in the form of a pump or a compressor. Without going beyond the ambit of the invention, it is also possible to mount the motor 4 and the inflator means 5 at another location, inside or even outside the container 2. The winding drum 3 is also provided with a tarpaulin starter section 31 that presents a length that is sufficient to enable the section 31 to project out from the slot 26 when it is completely unwound from the drum 3. The starter section 31 presents a free end that is provided with a fastener edge 36 for co-operating with a complementary connection edge 63 of a flexible tarpaulin 6. By way of example, the flexible tarpaulin 6 may be made out of a material that is generally used for survival blankets. By way of example, the material may be a metal- and or silver-plated polyester. This type of material is known for its considerable strength, its extreme fineness, and for its thermal insulation qualities. This is only an example, but naturally it is possible to make the tarpaulin of the invention with any film, woven or non-woven fabric, etc. Preferably, the tarpaulin is transparent so as to allow certain portions of the vehicle to be visible, such as the license plate, the tax disc, etc. The tarpaulin could also include a pocket for parking tickets. The starter section 31 may also be made of the same material as the tarpaulin 6. In order to connect the tarpaulin 6 to the starter section 31, the connection and fastener edges 63 and 36 may constitute a zip fastener, for example. Naturally, other known and conventional types of fastener may be used.

In the invention, the flexible tarpaulin 6 is provided with an inflatable hose 61, 62 that, in this non-limiting embodiment, extends in the form of a U-shape or of a cup. The term “inflatable hose” should be understood to mean a flexible hose having a section that varies as a function of the pressure of the fluid it contains. Preferably, the inflatable hose is completely flat when it is not subjected to fluid pressure, and it takes on a substantially-circular section when it is subjected to pressure. By way of example, this is the principle of fire hoses. In this embodiment, it should be considered that the tarpaulin 6 includes a single inflatable hose having a U shape: in a variant, it should also be considered that the tarpaulin 6 is provided with three inflatable hose sections, namely two substantially-longitudinal sections 61 that are interconnected via a transverse connection section 62. In this embodiment, the sections 61 are rectilinear and extend substantially parallel to the longitudinal direction L that coincides with the longitudinal direction of the vehicle. However, it should be observed that the hose sections 61 slope a little relative to the longitudinal direction L, such that their free ends are spaced further apart than their opposite ends that are interconnected via the transverse connection section 62. In a variant, the two hose sections 61 may be completely parallel, or they may extend in sloping manner in the opposite direction. It is also possible to make the hose sections 61 in non-rectilinear manner, e.g. undulating, curved, zig-zag, etc. However, it is important that the hose sections 61 extend over all, or a major part, of the longitudinal direction L. In the embodiment used to illustrate the present invention, there are two longitudinal hose sections 61, but more longitudinal sections could be provided or, on the contrary, only one longitudinal section. The FIG. 6 embodiment is a preferred embodiment, however it is not limiting. It enables the inflatable hose to be spread over a large and uniform area of the tarpaulin 6, covering all of its longitudinal extent. As mentioned above, the inflatable hose 61 has the ability to be inflated under pressure with a fluid that is generally air, but that may also be some other gas or even a liquid. To do this, the tarpaulin also incorporates a feed tube 65 that connects the inflatable hose 61 to the inflator means 5. More precisely, the feed tube 65 may be connected to a connection tube 56 that extends in the starter section 31, which connection tube is connected to a duct 55 that preferably extends inside the winding drum 3. Thus, the inflator means 5 are connected to the inflatable hose. The fluid under pressure fed by the pump 5 thus inflates the inflatable hose in such a manner as to impart a certain amount of stiffness. Thus, it can readily be understood that the inflation of the hose makes it possible to stiffen or rigidify the flexible tarpaulin 6. The flexible tarpaulin thus no longer behaves as a floppy material, but rather as a substantially-rigid plate. Directing the sections 61 in longitudinal manner makes it possible to impart particular rigidity to the tarpaulin 6 in the longitudinal direction L. Naturally, the fact that there are two longitudinal sections 61 makes it possible to reinforce the rigidity in the longitudinal direction. The transverse section 62 has practically no function other than to interconnect the two longitudinal sections 61. Advantageously, it should be observed that the feed tube 65 is connected to the inflatable hose at the junction section 62. Thus, the fluid under pressure arrives in the longitudinal sections 61 at the free end 6a of the tarpaulin. The advantage obtained by these characteristics is described below. In a variant that is not shown, it is also possible eliminate the feed tube 65 and to connect the connection tube 56 directly at the connection end 6b of the tarpaulin, such that the hose inflates starting from its portion that is still wound on the drum 3.

In addition to the inflatable hose, the tarpaulin also includes a plurality of lateral elastic strips 66 that make it possible to gather the tarpaulin in the direction perpendicular to the longitudinal direction L. The tarpaulin 6 is also provided with loops 67 that make it possible to fasten the tarpaulin laterally to fastener hooks F that are secured to the vehicle, as can be seen in FIGS. 1 and 4. It is thus possible to decrease its width, so as to be able to wind it onto the winding drum 3 through the slot 26 of the container 2. It can be seen that the slot 26 presents a length that is shorter than the width of the tarpaulin 6.

As described above, the flexible tarpaulin 6 is provided with one or more inflatable hoses 61, 62 that may be connected together in continuous manner or, on the contrary, that may be separate from each other. Also as described above, inflating the hoses under pressure makes it possible to rigidity them in such a manner as to impart a certain amount of stiffness to the flexible tarpaulin 6. In other words, the inflatable hose(es) constitute(s) stiffener means for stiffening the tarpaulin, which stiffener means may be activated or deactivated selectively by inflator means that perform an activator function acting directly on the stiffener elements. The stiffener elements may thus be switched selectively between an activated state in which they are substantially stiff, and a deactivated state in which they are substantially soft or floppy. In this embodiment, the two longitudinal stiffener elements 61 are interconnected via a stiffener junction element 62. However, it is quite possible to make the junction element 62 merely by means of a tube of a size that does not vary with pressure. It is also possible to imagine that the feed tube 65 forms a Y-shaped fork making it possible to feed two longitudinal stiffener elements 61 that are completely independent from each other. In this configuration, the junction element 62 could be eliminated.

The tarpaulin system of the invention may also include a traction device E, such as a mechanical winder having a return spring, which traction device is situated at the front of the vehicle. The traction device E includes a connection end that may be connected manually to the tarpaulin so as to hold it on the longitudinal axis of the vehicle. The function of the traction device E is not to wind out the tarpaulin, but merely to avoid it deviating from its path while it is being wound out: it may be considered as longitudinal guide means. During winding in, the traction device is not necessary.

Reference is made once again to FIGS. 1 to 4 in or order to explain below a complete operating cycle for covering a motor vehicle V with the tarpaulin. In FIGS. 1 and 5, it can be seen that the tarpaulin 6 is wound almost entirely on the winding drum 3 that is situated inside the container 2 that is housed inside the rear bumper P of the vehicle V. Only the free end 6a of the tarpaulin 6 projects out from the container 2 through the slot 26, such that the end 6a is already positioned at the rear end of the trunk M. In FIG. 5, which is a larger-scale view, it can be seen that the slot 26 is provided with an outlet deflector 27 that is directed in sloping manner towards the vehicle, so as to constrain the tarpaulin 6 to extend towards the top of the vehicle. Advantageously, the outlet deflector 27 is mounted on the slot 26 in hinged manner at 28, and may thus serve as a closure lid for closing the slot 26 when the tarpaulin is in its completely wound-in position inside the container 2. Naturally, it is necessary to hold the free end 6a inside the slot 26, so as to enable the tarpaulin to poke out from the container 2 and from its slot 26. The outlet deflector 27 may be actuated mechanically or electrically. The configuration shown in FIGS. 1 and 5 corresponds to the very start of the operation of applying the tarpaulin, just after the deflector 27 has been put into its operational position, with the free end 6a poking out from the container 2. In order to enable the intrinsically-flexible tarpaulin 6 to poke out from the slot 26 automatically, the activator or inflator means 5 are actuated in such a manner as to inject fluid under pressure into the inflatable hose(s). This causes the flexible tarpaulin 6 to rigidify, at least locally, thereby enabling it to poke out from the slot 26 with a certain amount of rigidity. It is this that is shown in FIGS. 1 and 5. Naturally, switching on the activator or inflator means 5 should be coordinated with activating the motor 4 for turning the drum 3. Thus, simultaneously, fluid is injected into the inflatable hose, and the tarpaulin is wound out from the shaft 3. The tarpaulin 6 continues to wind out with a certain amount of rigidity over the vehicle, with the hoses under pressure, as shown in FIG. 2. The tarpaulin 6 is constrained to extend over the vehicle under the action of the outlet deflector 27 that forces it to follow a predetermined direction. The tarpaulin continues to be wound out and the hose 61 continues to be inflated until the tarpaulin 6 covers the vehicle V, as can be seen in FIG. 3. The tarpaulin 6 is not yet in its final operational position, but both the activator means 5 and the motor 4 may be deactivated from this moment. This causes the hoses 61 to deflate, and the tarpaulin to return to its naturally-flexible state. The tarpaulin may thus match the outside shapes of the vehicle. It suffices for the user to put the loops 67 into place on the hooks F, and to surround the front bumper with the free end 6a. This is shown in FIG. 4. The flexible hose 61 is once again flat, and no longer imparts any rigidity to the tarpaulin. In a variant, it is possible to conserve the hoses in the inflated state so as to impart a rounded-shell configuration to the tarpaulin.

The operation of removing or of winding in the tarpaulin is conventional: it suffices to switch on the motor 4 so as to wind the tarpaulin onto the drum 3 without activating the means 5, since they perform absolutely no role during this operation. Once the tarpaulin is wound completely into the container 2, it suffices to close the deflector lid 27 so as to close the slot 26.

The slightly-sloping orientation of the inflatable hoses and of the feed tube has the advantage of not accumulating thickness on the drum 3 inside the container 2. By sloping the hoses and tubes slightly, said hoses and tubes wind around the tube 3 in helical spirals, and not onto themselves, thereby avoiding any excess thickness inside the container 2 that could impede proper operation of the tarpaulin system of the invention.

The tarpaulin may also be provided with accessories, e.g. a copy of the license plate, a transparent pocket, solar cells, etc.

The motor 4 and the inflator means 5 are powered by the battery of the vehicle or by a dedicated battery. Solar cells may contribute power.

Reference is made below to FIG. 7 in order to describe a variant of the first embodiment in FIG. 6. In this variant, the tarpaulin system also comprises a container 2 provided with a slot 26, a winding drum 3, a motor 4, inflator means 5, a flexible tarpaulin 6 that is windable on the drum 3, two inflatable hoses 61, and two feed tubes 65. These elements may be similar or identical to the elements of the FIG. 6 embodiment. However, this variant embodiment differs from the FIG. 6 embodiment in that the inflatable hoses 61 are not incorporated in the tarpaulin 6, but, on the contrary, they are situated laterally on either side of the tarpaulin 6, being connected only at the free end of the flexible tarpaulin 6 by fastenings 68. In order to maintain the spacing between the fastenings 68, the flexible tarpaulin 6 may be provided with a spacer 62′ that performs a transverse stiffener role. The two inflatable hoses 61 are windable on the drum 3, as in the embodiment in FIG. 6. However, although the hoses 61 are incorporated in the tarpaulin 6 in FIG. 6, the inflatable hoses 61 in FIG. 7 are separate from the tarpaulin 6, except at the fastenings 68, and as a result, the hoses 61 are wound on the shaft 3 independently of the tarpaulin 6. More precisely, it can be seen in FIG. 7 that the container 2 is sub-divided into a plurality of compartments 21, 22, and 23 with the winding drum 3 passing through all of them. The central compartment 21, that is the largest compartment, is for receiving the tarpaulin 6. On either side of the compartment 21, there are respective side compartments 22 for receiving the flexible hoses 61. Finally, on the outside, there are two compartments 23 for receiving the flexible feed tubes 65 that are also wound directly on the shaft 3. Thus, rather than wind in the tarpaulin 6, and the hoses 61, and/or the tubes 65 together, as in FIG. 6, the variant embodiment in FIG. 7 envisages winding in all of these elements separately, so as to avoid any accumulation of thickness that would be detrimental to the size and to the compactness of the container 2. By means of this configuration, it is possible to limit the diameter of the container 2 considerably. The length of the container 2 is increased a little, but this increase is minimal, given that the compartments 22 and 23 do not need to be very wide.

According to another advantageous characteristic of this variant embodiment, the tarpaulin system is provided with guide means 7 for longitudinally guiding the strips 61 while they are being wound out. In order to be able to wind the strips in correctly, it is preferable to guide them completely, so as to avoid any sideways deviation of the tarpaulin. By way of example, the guide means may be housed inside the compartment 22. By way of example, they may comprise two presser rollers 71, 72 that are urged against each other so as to generate local pinching. The strips 61 pass between, and are guided by, the two presser rollers 71, 72 that thus prevent any flow inside of the hose. In this way, the portion of the hose that is wound on the drum 3 inside the compartment 22 is not inflated, since the air under pressure is prevented from propagating inside this portion of the hose, as a result of the local airtight pinching generated by the two presser rollers 71, 72. This is shown diagrammatically in FIG. 8a. FIGS. 8b and 8c are very diagrammatic, showing the configuration of the tarpaulin 6 and of the tubes 65 inside the compartments 21 and 23 respectively. It should be observed that this local airtight pinching device 7 may also be used in the embodiment in FIG. 6.

The operation of the tarpaulin system in FIG. 7 is similar to the operation of the tarpaulin system in FIG. 6. When it is desired to cover the vehicle in the tarpaulin, both the motor 4 and the inflator means 5 are actuated so that the tarpaulin 6 winds out from its drum 3, and the hoses 61 are inflated via the tubes 65. It should be observed that the inflation of the hoses 61 contributes to them winding out from the drum 3. The portions of the hoses 61 that are already inflated and that are situated outside the compartments 22 stiffen and drive the tarpaulin 6, since it is connected at the fastenings 68. As in the embodiment in FIG. 6, the tarpaulin 6 and the inflated hoses 61 deviate in appropriate manner, e.g. by means of the deflector 27, so as to direct the tarpaulin over the top of the vehicle. When the operation of applying the tarpaulin is terminated, both the motor 4 and the inflator means 5 are interrupted. The user can thus manually terminate the securing of the tarpaulin over the vehicle, as described above. The operation of removing the tarpaulin is strictly identical to the operation described above, involving actuating the motor 4 so as to wind the tarpaulin 6, the inflated hoses 61, and the tubes 65 onto the winding drum 3, separately into their dedicated compartments. When the operation of removing the tarpaulin is terminated, the tarpaulin 6, the deflated hoses 61, and the tubes 65 remain connected together at the spacer 62′ via the fastenings 68.

FIGS. 9 and 10 show a preferred embodiment that differs from the above-mentioned embodiments by the following characteristics:
the lateral feed tube 65 extends along only one side of the tarpaulin, and then extends transversally so as to connect to the other inflatable hose 61;
the tarpaulin forms a zone Z that is covered in photovoltaic cells so as to produce electricity that can be used by the vehicle, in particular when said vehicle is an electric vehicle, in full or in part; and
the guide means 7 comprise two presser rollers 71, 72 that are shaped, as is the hose or strip 61 so as to improve the guidance and the local pinching thereof.

Reference is made below to FIGS. 11, 12, and 13 in order to describe a second embodiment that differs from the above-mentioned embodiments mainly in that it does not use inflatable hoses as stiffener elements. In this embodiment, the stiffener elements 61′ are in the form of windable strips that extend on either side of the tarpaulin 6. The strip 61′ is connected to the free end of the tarpaulin 6 by fastenings 68 in the proximity of the spacer 62′, as in the above-mentioned embodiment in FIG. 7. In other words, the strip 61′ is connected to the tarpaulin only at the fastenings 68. By way of example, the windable strip 61′ is in the form of a shaped metal strip that extends in straight and rigid manner in its wound-out state, while conserving the possibility of being wound in. Such a strip is already known in the prior art, in particular in its use as a roll-up tape rule. The strip may thus be slightly concave, thereby enabling it to impart a certain amount of rigidity thereto in its wound-out state, while enabling it to be windable. In the context of the invention, and by way of example, it is possible to use a windable strip 61′ that is urged by a spring into its wound-in state around a specific winding shaft 83 that is distinct from the winding drum 3. This is shown in FIG. 12. By way of example, the strip 61′ may be housed inside a casing 8 like a conventional roll-up tape rule. In order to extract and pull the strip 61′ out from its casing 8, the invention provides an ingenious drive system that uses the drive force of the winding drum 3. More precisely, a bearing roller 9 urges the strip 61′ against the shaft 3 in such a manner that the shaft 3 pulls the strip 61′. Advantageously, provision may be made to notch a face of the strip 61′ and the portion of the drum 3 that comes into contact with the strip 61′, in such a manner as to generate drive of the rack-and pinion type. The bearing roller 9 thus ensures that the strip 61′ and the drum 3 mesh well. Naturally, in place of the bearing roller 9, it is possible to provide any other device that can guarantee effective contact between the strip 61′ and the drum 3.

As in the variant embodiment in FIG. 7, the container 2 is divided into a plurality of compartments 21 and 24: the central compartment 21 receives the wound-in tarpaulin 6, while the side compartments 24 receive the casing 8 with its wound-in strip and the bearing roller 9.

In a variant shown in FIG. 13, the tarpaulin system may include guide means in the form of two rollers 71′ and 72′ between which the strip 61′ passes and is guided. More precisely, the roller 71′ forms two rows of sprockets 75 that penetrate into two rows of recesses 76 that are formed by the second roller 72′. The strip 61′ is made with two rows of lateral perforations like a cinematographic film strip, such that the sprockets 75 penetrate into the recesses so as to cause the strip 61′ to move. In order to turn the rollers, the roller 72′ may be coupled to the drum 3 via a drive system having wheels 73, 33 and a belt 74.

The advantage of this second embodiment is that is does not need to be used with inflator means, the only electrical element being the drive motor 4 that makes it possible to wind in and wind out the strips and the tarpaulin simultaneously.

In all of the embodiments, the stiffener elements 61 and 61′ are windable either directly onto the drum 3, or onto a separate shaft such as the shaft 83, by means of a motor. It should also be observed that in their wound-in state, the stiffener elements do not perform any stiffening function, such that they adopt two completely different states.

By means of the invention, the flexible tarpaulin incorporates stiffener means that act only during the operation of applying the tarpaulin or of winding out the tarpaulin, and that are completely without function and invisible during the operation of removing the tarpaulin or of winding in the tarpaulin.

1. A protective tarpaulin system (1) for a motor vehicle (V), such as a car, said system comprising a flexible tarpaulin (6) for covering the vehicle (V), at least in part, so as to protect it, the tarpaulin (6) defining a longitudinal direction (L) that extends lengthwise over the vehicle, the tarpaulin (6) being provided with at least one stiffener element (61; 61′) that extends substantially in the longitudinal direction (L) so as to impart longitudinal stiffness to the flexible tarpaulin so as to make the operation of covering the vehicle with the tarpaulin easier, the system further comprising a winding drum (3) that is advantageously installed at the rear bumper of the vehicle, the tarpaulin (6) being windable onto the drum (3) between a wound-in storage position and a wound-out covering position, said at least one stiffener element (61; 61′) extending substantially perpendicularly to the drum (3), said at least one stiffener element being windable onto the winding drum (3) or onto a winding shaft (83) that is distinct from the drum (3), said system being characterized in that it further comprises a motor (4) for turning the winding drum (3) about its own axis.

2. A tarpaulin system according to claim 1, further comprising guide means (7;
E) for longitudinally guiding said at least one stiffener element while it is being wound in and/or wound out.

3. A tarpaulin system according to claim 2, wherein the guide means (7) comprise two rotary presser rollers (71, 72) between which the stiffener element passes while it is being wound out and/or wound in.

4. A tarpaulin system according to claim 1, wherein said at least one stiffener element (61) is provided with activator means (5) that act on the stiffener element (61) so as to switch it selectively between an activated state in which the stiffener element is substantially stiff, and a deactivated state in which the stiffener element is limp, said at least one stiffener element (61) comprising an inflatable hose that is inflated with a fluid under pressure, the activator means comprising inflator means (5), such as a pump or a compressor, that are in fluid communication with said at least one stiffener element (61).

5. A tarpaulin system according to claim 4, wherein the tarpaulin (6) includes a free end (6a) for covering the front of the vehicle, and a connection end (6b) that is secured to the winding drum (3), said at least one stiffener element (61) extending between the free and connection ends (6a, 6b), the inflator means (5) being connected to said at least one stiffener element (61) via a feed tube (65) that is connected to said stiffener element (61) in the proximity of the free end (6a), so as to inflate it from the free end to the connection end (6b).

6. A tarpaulin system according to claim 5, wherein the guide means (7) comprise two rotary presser rollers (71, 72) that exert local leaktight pinching on the inflatable hose while it is being wound out, thereby preventing the portion that is still wound on the drum (3) from being inflated.

7. A tarpaulin system according to claim 5, wherein the tarpaulin (6), the stiffener element (61), and the feed tube can be wound around the winding drum (3) in separate manner, so as to avoid creating excess thickness in the wound state.

8. A tarpaulin system according to claim 1, wherein said at least one stiffener element comprises a windable strip (61′) that is substantially straight and rigid in its wound-out state.

9. A tarpaulin system according to claim 8, wherein the strip (61′) is wound around a specific winding shaft (83) that extends parallel to the winding drum (3), the strip advantageously being driven towards its wound-out state by the drum.

10. A tarpaulin system according to claim 1, wherein said at least one stiffener element (61, 61′) is connected to the tarpaulin (6) only at its free end (6a) for covering the front of the vehicle, so as to enable the stiffener element and the tarpaulin to be wound separately.

11. A tarpaulin system according to claim 1, wherein the drum (3) is housed in a container (2) that is advantageously installed at the rear bumper of the vehicle, the container (2) including an elongate slot (26) through which the tarpaulin (6) can pass, the slot (26) being provided with an outlet deflector (27) that is suitable for directing the tarpaulin (6) towards the top of the vehicle while the tarpaulin is being unwound, the deflector (27) advantageously serving as a pivoting closure lid for closing the slot (26).

12. A tarpaulin system according to claim 1, the guide means comprise a traction device (E) that is situated at the front of the vehicle, and that is connectable to the tarpaulin (6) so as to guide it in the longitudinal direction.

13. A tarpaulin system according to claim 1, wherein the tarpaulin (6) includes a zone (Z) that is covered in photovoltaic cells.
